(19) United States
(12) Patent Application Publication
(10) Pub. No.: US 2026/0130138 A1
(43) Pub. Date: May 7, 2026

(54) METHOD FOR MANUFACTURING OXIDE LAYER AND SEMICONDUCTOR DEVICE

(71) Applicants: Semiconductor Technology Innovation Center (Beijing) Corporation, Beijing (CN); INSTITUTE OF MICROELECTRONICS, CHINESE ACADEMY OF SCIENCES, Beijing (CN)

(72) Inventors: Hong YANG, Beijing (CN); Songyi JIANG, Beijing (CN); Junjie LI, Beijing (CN); Weihai BU, Beijing (CN); Qianqian LIU, Beijing (CN); Xiaolei WANG, Beijing (CN); Jun LUO, Beijing (CN); Wenwu WANG, Beijing (CN)

(21) Appl. No.: 19/213,320

(22) Filed: May 20, 2025

(30) Foreign Application Priority Data
Nov. 7, 2024 (CN) 202411587003.X

(51) Int. Cl. H01L 21/02

(52) U.S. Cl. CPC H10P 14/6319

(57) ABSTRACT

The present disclosure discloses a method for manufacturing an oxide layer and a semiconductor device, which pertain to the field of semiconductor technology. The method for manufacturing the oxide layer includes: providing a semiconductor structure; forming a first oxide layer on the semiconductor structure in a first low-temperature environment; applying an oxygen plasma treatment on the first oxide layer and a part of the semiconductor structure in a second low-temperature environment, so that the first oxide layer is formed into a second oxide layer, where a compactness of the second oxide layer is greater than a compactness of the first oxide layer. The semiconductor device includes a semiconductor structure and a second oxide layer disposed on the semiconductor structure, where the second oxide layer is manufactured and formed using the aforementioned oxide layer fabrication method.

### CROSS REFERENCE TO RELATED APPLICATION

This application claims priority to Chinese Patent Application No. 202411587003.X, filed on Nov. 7, 2024, the entire content of which is incorporated herein in its entirety by reference.

### TECHNICAL FIELD

The present disclosure pertains to the field of semiconductor technology, in particular to a method for manufacturing an oxide layer and a semiconductor device.

### BACKGROUND

With continuous development of large-scale integrated circuit technology, higher requirements are imposed on oxide layers generally included in a transistor. On the one hand, due to the continuous reduction in the size of the transistor, there is an increasing requirement for a thermal budget in a process of manufacturing the transistor, which proposes higher requirements for the process of manufacturing the oxide layer. On the other hand, in order to meet requirements of performance and reliability for different transistors, the oxide layer needs to have good compactness, and it is required to precisely adjust a thickness of the oxide layer within a large range.

However, related manufacturing methods are difficult to achieve the manufacturing of high compactness and thickness controllable oxide layers in a low-temperature environment, leading to degraded device performance and reliability of the semiconductor device including such oxide layer.

### SUMMARY

In a first aspect, the present disclosure provides a method for manufacturing an oxide layer. The method for manufacturing the oxide layer includes the following steps. Firstly, providing a semiconductor structure. Next, a first oxide layer is formed on the semiconductor structure in a first low-temperature environment. Next, an oxygen plasma treatment is performed on the first oxide layer and a part of the semiconductor structure in a second low-temperature environment, so that the first oxide layer is formed into a second oxide layer. A compactness of the second oxide layer is greater than a compactness of the first oxide layer.

In a case of adopting the above technical solution, the semiconductor structure is first subjected to pre-oxidation in a low-temperature ambient, so as to form a first oxide layer with relatively low compactness, and serves as a precursor for subsequent formation of the second oxide layer. Afterwards, in the second low-temperature environment, an oxygen plasma treatment is employed to facilitate reaction with the first oxide layer and a part of the semiconductor structure, so as to form the second oxide layer. The second oxide layer is used as the oxide layer manufactured by the method for manufacturing the oxide layer provided by the present disclosure.

The formation of the second oxide layer using oxygen plasma includes the following steps. Firstly, oxygen is ionized into an oxygen plasma containing a plurality of reactive chemical species such as oxygen ions, oxygen radicals, and electrons through a radio frequency power supply. Then, the oxygen plasma is charged and accelerated through the radio frequency power supply, and the accelerated oxygen plasma undergoes directed bombardment of surfaces of the first oxide layer and the part of the semiconductor structure, so as to react with the first oxide layer and the part of the semiconductor structure. Since these oxygen plasmas have stronger oxidation ability compared to reactants in other oxidation processes, the first oxide layer and the part of the semiconductor structure may be fully oxidized, so as to form a relatively compact second oxide layer. At the same time, these oxygen plasmas accelerated by the radio frequency power supply have higher energy, which may penetrate the first oxide layer and the formed part of the second oxide layer, and may be injected into an interior of the semiconductor structure to oxidize atoms inside the semiconductor structure, so that a thickness of the formed second oxide layer has a large adjustment range, which is not prone to the limitation of thickness saturation of the oxide layer due to the oxidation of the surface of the semiconductor structure. In addition, the oxygen plasma adheres to plasma dynamics principles, and a relationship between a treatment time and the thickness of the oxide layer formed by performing an oxygen plasma treatment on the first oxide layer and the part of the semiconductor structure may be precisely described. Therefore, the thickness of the second oxide layer may be precisely controlled by controlling the time of the oxygen plasma treatment. Compared to the related art, the method for manufacturing the oxide layer provided by the embodiments of the present disclosure may be used to obtain a second oxide layer with high compactness, high thickness adjustment accuracy and large thickness adjustment range, and the semiconductor device including the second oxide layer have better reliability.

However, in the related art, if only the oxygen plasma treatment is used to form the second oxide layer, in order to ensure that the second oxide layer has good compactness, the oxygen plasma treatment requires to be performed in a high-temperature environment, which generally results in a higher thermal budget. In the method for manufacturing the oxide layer provided by the present disclosure, the semiconductor structure is first pre-oxidized in the first low-temperature environment, so as to form a first oxide layer with relatively low compactness. Although the first oxide layer exhibits reduced compactness and inferior quality, a preliminary oxidization may be performed on the semiconductor structure, so that there is no need for starting from scratch in the subsequent oxygen plasma treatment, thereby reducing a radio frequency power, a treatment time and a treatment temperature required for forming the second oxide layer through the oxygen plasma treatment, so that the oxygen plasma treatment may be performed on the second oxide layer in the second low-temperature environment, significantly reducing the thermal budget. In addition, the process of forming the first oxide layer may be performed in the first low-temperature environment. Combined with the aforementioned, a total thermal budget of forming the first oxide layer and the second oxide layer is still lower than a thermal budget of forming the second oxide layer only through the oxygen plasma treatment. The method for manufacturing the oxide layer provided by the present disclosure has a lower thermal budget, which may effectively reduce thermally induced degradation of the semiconductor device including the oxide layer during the process of manufacturing the oxide layer.

As a possible embodiment, a temperature of the first low-temperature environment is less than or equal to 400° C.

In a case of adopting the above technical solution, the thermal budget of the method for manufacturing the oxide layer provided by the present disclosure may be further reduced.

As a possible embodiment, a temperature of the second low-temperature environment is less than or equal to 400° C.

In a case of adopting the above technical solution, the thermal budget of the method for manufacturing the oxide layer provided by the present disclosure may be further reduced.

As a possible embodiment, the forming of a first oxide layer on the semiconductor structure includes: submerging the semiconductor structure in an aqueous ozone solution to oxidize the semiconductor structure, so as to form the first oxide layer.

In a case of adopting the above technical solution, a relatively loose and non-compact first oxide layer may be formed by pre-oxidizing the semiconductor structure using ozone water oxidation as a chemical oxidation method, which facilitates the oxygen plasma to enter the first oxide layer and to oxidize the first oxide layer and the part of the semiconductor structure when the subsequent oxygen plasma treatment is performed on the semiconductor structure, so as to form the second oxide layer. Moreover, the semiconductor structure is pre-oxidized using the ozone water oxidation, and the thickness of the formed first oxide layer is relatively thin, which may avoid the thickness of the subsequent formed second oxide layer does not meet a practical requirement (e.g. when the second oxide layer is a thinner oxide layer such as an interface layer) due to the large thickness of the first oxide layer, thereby reducing the thickness range of the oxide layer manufactured by the method for manufacturing the oxide layer provided by the present disclosure. In addition, since a solution wet processing is used, the temperature of the first low-temperature environment is lower, which is beneficial for reducing the thermal budget of the method for manufacturing the oxide layer provided by the present disclosure.

As a possible embodiment, an ozone concentration in the aqueous ozone solution is greater than or equal to 3 ppm and less than or equal to 100 ppm.

In a case of adopting the above technical solution, the ozone concentration in the aqueous ozone solution is within the above range, which may avoid that the formed oxide layer with poor compactness, poor quality and too thin thickness since the ozone concentration is too low, and may further avoid higher energy required for subsequent oxygen plasma treatment (which requires greater radio frequency power, longer treatment time and higher treatment temperature), thereby ensuring the thermal budget of the method for manufacturing the oxide layer provided by the present disclosure. Moreover, a large amount of ozone escaping from the solution due to the too high ozone concentration may also be avoided, which is beneficial for reducing the usage amount of consumables and controlling manufacturing costs.

As a possible embodiment, an oxidation time of submerging the semiconductor structure in the aqueous ozone solution is greater than or equal to 3 seconds and less than or equal to 100 seconds.

In a case of adopting the above technical solution, the oxidation time of submerging the semiconductor structure in the aqueous ozone solution is within the above range, which may avoid that the formed first oxide layer with poor compactness and poor quality since the oxidation time is too short, and may further avoid higher energy required for subsequent oxygen plasma treatment (which requires greater radio frequency power, longer treatment time and higher treatment temperature), thereby ensuring the thermal budget of the method for manufacturing the oxide layer provided by the present disclosure. Moreover, the excessive amount of ozone escaping from the solution due to the too long oxidation time may also be avoided, which is beneficial for reducing the usage amount of consumables and controlling manufacturing costs.

As a possible embodiment, a thickness of the second oxide layer is greater than or equal to 0.5 nm and less than or equal to 5 nm.

In a case of adopting the above technical solution, the thickness of the second oxide layer may be adjusted within a large range, and the second oxide layer may have a large application range, thereby expanding the application scope of the method for manufacturing the oxide layer provided by the present disclosure.

As a possible embodiment, a treatment temperature during the oxygen plasma treatment is greater than or equal to 200° C. and less than or equal to 400° C.

In a case of adopting the above technical solution, the treatment temperature of the oxygen plasma treatment is within the above range, which may avoid the thickness and compactness of the formed second oxide layer do not meet the design requirements due to too low treatment temperature. In addition, a significant increase in thermal budget due to excessively high treatment temperature may also be avoided, thereby ensuring the thermal budget of the method for manufacturing the oxide layer provided by the present disclosure.

As a possible embodiment, radio frequency power of the oxygen plasma treatment is greater than or equal to 500 W and less than or equal to 1000 W.

In a case of adopting the above technical solution, the radio frequency power of the oxygen plasma treatment is within the above range, which may avoid the problem that after forming the second oxide layer with a certain thickness, the energy of the oxygen plasma is too low to effectively penetrate the first oxide layer and semiconductor structure since the radio frequency power is too low, and may further avoid the second oxide layer formed by oxygen plasma treatment reach a saturation thickness which cannot be further increased, thereby ensuring the adjustment range of the thickness of the oxide layer formed by the method for manufacturing the oxide layer provided by the present disclosure. An incomplete ionization of oxygen due to the too low radio frequency power may also be avoided, which may further avoid poor oxidation of oxygen plasma, thereby ensuring the compactness and quality of the second oxide layer formed by oxygen plasma treatment. Excessive reflection generated by oxygen plasma bombardment of the first oxide layer and semiconductor structure due to the too large radio frequency power of the oxygen plasma treatment may also be avoided, which may further avoid damage to the oxygen plasma treatment device, thereby ensuring the normal operation of the device.

As a possible embodiment, a treatment time of the oxygen plasma treatment is greater than or equal to 5 seconds and less than or equal to 1 hour.

In a case of adopting the above technical solution, the treatment time of the oxygen plasma treatment is within the above range, which may avoid the compactness and thickness of the formed second oxide layer do not meet the design requirements due to too short treatment time, thereby ensuring the performance of the oxide layer manufactured by the method for manufacturing the oxide layer provided by the present disclosure. Moreover, a significant increase in thermal budget due to too long treatment time of the oxygen plasma treatment may also be avoided, thereby ensuring the thermal budget of the method for manufacturing the oxide layer provided by the present disclosure.

As a possible embodiment, the second oxide layer includes an interface oxide layer.

In a case of adopting the above technical solution, the second oxide layer manufactured by the method for manufacturing the oxide layer provided by the present disclosure has a thinner thickness, and the method for manufacturing the oxide layer provided by the present disclosure may be used as the method for manufacturing the interface oxide layer.

As a possible embodiment, a material of the semiconductor structure includes silicon.

In a case of adopting the above technical solution, the method for manufacturing the oxide layer provided by the present disclosure has good compatibility with the most common related material (that is, silicon), thereby expanding the application scope of the method for manufacturing the oxide layer provided by the present disclosure.

As a possible embodiment, the semiconductor structure includes a source region, a drain region, and a channel region located between the source region and the drain region. The channel region adjoins the source region and the drain region along its longitudinal axis at opposing ends. The second oxide layer is formed on the periphery of the channel region.

In a case of adopting the above technical solution, since the second oxide layer manufactured by the method for manufacturing the oxide layer provided by the present disclosure has a relatively thin thickness, the method for manufacturing the oxide layer provided by the present disclosure may be used as the method for manufacturing the interface layer.

In a second aspect, the present disclosure provides a semiconductor device. The semiconductor device includes a semiconductor structure and a second oxide layer disposed on the semiconductor structure, where the second oxide layer is manufactured and formed using the manufacturing method provided in the first aspect. The beneficial effects of the semiconductor device provided by the present disclosure may refer to the related description of the first aspect, which will not be repeated here.

### BRIEF DESCRIPTION OF THE DRAWINGS

The accompanying drawings described herein are intended to provide a further understanding of the present disclosure and form a part of the present disclosure. The illustrative embodiments of the present disclosure and their description are used to explain the present disclosure and do not constitute undue limitation of the present disclosure. In the accompanying drawings:

FIG. 1 is a flowchart of a method for manufacturing an oxide layer provided by an embodiment of the present disclosure;

FIG. 2 is a schematic diagram of providing a semiconductor structure in an embodiment of the present disclosure;

FIG. 3 is a schematic diagram of forming a first oxide layer in an embodiment of the present disclosure;

FIG. 4 is a schematic diagram of forming a second oxide layer in an embodiment of the present disclosure;

FIG. 5 is a curve graph of an increased thickness of a second oxide layer compared to a first oxide layer and an oxygen plasma treatment time in an embodiment of the present disclosure;

FIG. 6 is a schematic diagram of an increased compactness and reliability of a second oxide layer compared to a first oxide layer in an embodiment of the present disclosure.

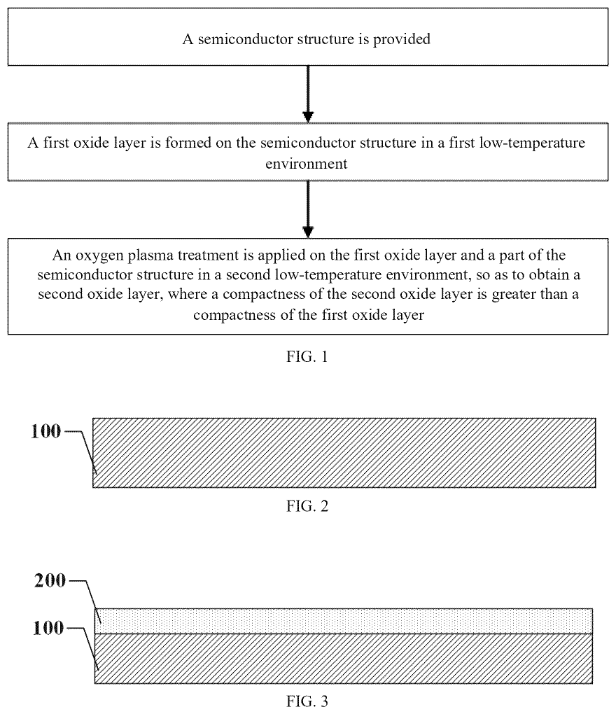

### REFERENCE SIGNS

100—Semiconductor structure, 200—First oxide layer,
300—Second oxide layer.

### Detailed Description of Embodiments

In order to make the technical problems to be solved, technical solutions, and beneficial effects of the embodiments of the present disclosure clearer and more understandable, the embodiments of the present disclosure will be further described in detail with reference to the accompanying drawings and embodiments. It should be understood that the specific embodiments described here are only used to explain the embodiments of the present disclosure and are not intended to limit the embodiments of the present disclosure.

It should be noted that when an element is referred to as “fixed on” or “disposed on” another element, it may be directly or indirectly on the another element. When an element is referred to as “connected to” another element, it may be directly connected to the another element or may be indirectly connected to the another element.

In addition, the terms “first” and “second” are only used for descriptive purposes and cannot be understood as indicating or implying relative importance or implying the number of technical features indicated. Thus, the features defined with “first” and “second” may explicitly or implicitly include one or more of these features. In the description of the embodiments of the present disclosure, the meaning of “multiple” refers to two or more, unless otherwise specifically limited. The meaning of “several” refers to one or more, unless otherwise specifically specified.

In the description of the embodiments of the present disclosure, it should be understood that the terms “up”, “down”, “front”, “back”, “left”, “right”, etc. indicate orientation or positional relationships based on the orientation or positional relationships shown in the accompanying drawings, only for the convenience of describing the embodiments of the present disclosure and simplifying the description, rather than indicating or implying that the device or element referred to must have a specific orientation, be constructed and operated in a specific orientation, and therefore cannot be understood as limiting the embodiments of the present disclosure.

In the description of the embodiments of the present disclosure, it should be noted that unless otherwise specified and limited, the terms “mount”, “link”, and “connect” should be broadly understood, for example, they may be fixed connections, detachable connections, or integrated connections. It may be a mechanical connection or an electrical connection. It may be directly connected or indirectly connected through an intermediate medium, and it may be an inner connection within two elements or an interaction relationship between two elements. For those of ordinary skill in the art, the specific meanings of the above terms in the embodiments of the present disclosure may be understood according to the specific situation.

The purpose of the embodiments of the present disclosure is to provide a method for manufacturing an oxide layer and a semiconductor device, for forming an oxide layer with high quality, high compactness, large thickness adjustment range, and high adjustment accuracy on a semiconductor structure in a low-temperature environment.

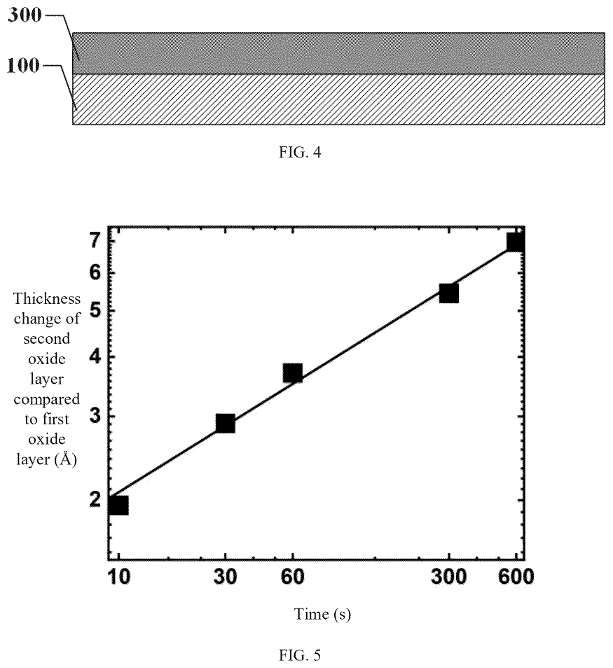

In order to achieve the above purposes, in the first aspect, the embodiments of the present disclosure provide a method for manufacturing an oxide layer. The method for manufacturing the oxide layer includes the following steps. Firstly, referring to FIG. 2, a semiconductor structure 100 is provided. Next, referring to FIG. 3, a first oxide layer 200 is formed on the semiconductor structure 100 in a first low-temperature environment. Next, referring to FIG. 4, an oxygen plasma treatment is performed on the first oxide layer 200 and a part of the semiconductor structure 100 in a second low-temperature environment, so that the first oxide layer 200 is formed into a second oxide layer 300. A compactness of the second oxide layer 300 is greater than a compactness of the first oxide layer 200.

In a case of adopting the above technical solution, referring to FIG. 3, firstly, the semiconductor structure 100 is subjected to pre-oxidation in a low-temperature ambient to form the first oxide layer 200 with relatively low compactness. The first oxide layer 200 facilitates the formation of the second oxide layer 300. Afterwards, referring to FIG. 4, in the second low-temperature environment, the oxygen plasma oxidation treatment is used to react the oxygen plasma with the first oxide layer 200 and a part of the semiconductor structure 100, so as to form the second oxide layer 300. The second oxide layer 300 is used as the oxide layer manufactured by the method for manufacturing the oxide layer provided by the embodiments of the present disclosure.

The formation of the second oxide layer using oxygen plasma includes the following steps. Firstly, oxygen is excited into an oxygen plasma containing a plurality of reactive chemical species such as oxygen ions, oxygen radicals, and electrons before the reaction. Then, the oxygen plasma is charged and accelerated through a radio frequency power supply, and the accelerated oxygen plasma undergoes directed bombardment of surfaces of the first oxide layer and the part of the semiconductor structure, so as to react with the first oxide layer and the part of the semiconductor structure. Since these oxygen plasmas have stronger oxidation ability compared to reactants in other oxidation processes, the first oxide layer and the part of the semiconductor structure may be fully oxidized, so as to form a relatively compact second oxide layer. At the same time, these oxygen plasmas accelerated by the radio frequency power supply have higher energy, which may penetrate the first oxide layer and the formed part of the second oxide layer, and may be injected into an interior of the semiconductor structure to oxidize atoms inside the semiconductor structure, so that a thickness of the formed second oxide layer has a large adjustment range, which is not prone to the limitation of thickness saturation of the oxide layer due to the oxidation of the surface of the semiconductor structure. In addition, the oxygen plasma adheres to plasma dynamics principles, and a relationship between a treatment time and the thickness of the oxide layer formed by performing an oxygen plasma treatment on the first oxide layer and the part of the semiconductor structure may be precisely described. Therefore, the thickness of the second oxide layer may be precisely controlled by controlling the time of the oxygen plasma treatment. Compared to the related art, the method for manufacturing the oxide layer provided by the embodiments of the present disclosure may be used to obtain a second oxide layer with high compactness, high thickness adjustment accuracy and large thickness adjustment range.

However, in the related art, if only the oxygen plasma treatment is used to form the second oxide layer, in order to ensure that the second oxide layer has good compactness, the oxygen plasma treatment requires to be performed in a high-temperature environment, which generally results in a higher thermal budget. In the method for manufacturing the oxide layer provided by the embodiments of the present disclosure, the semiconductor structure is first pre-oxidized in the first low-temperature environment, so as to form a first oxide layer with relatively low compactness. Although the first oxide layer exhibits reduced compactness and inferior quality, a preliminary oxidization may be performed on the semiconductor structure, so that there is no need for starting from scratch in the subsequent oxygen plasma treatment, thereby reducing a radio frequency power, a treatment time and a treatment temperature required for forming the second oxide layer through the oxygen plasma treatment, so that the oxygen plasma treatment may be performed on the second oxide layer in the second low-temperature environment, significantly reducing the thermal budget. In addition, the process of forming the first oxide layer may be performed in the first low-temperature environment. Combined with the aforementioned, a total thermal budget of forming the first oxide layer and the second oxide layer is still lower than a thermal budget of forming the second oxide layer only through the oxygen plasma treatment. The method for manufacturing the oxide layer provided by the embodiments of the present disclosure has a lower thermal budget, which may effectively reduce the thermal damage of the semiconductor device including the oxide layer during the process of manufacturing the oxide layer.

In addition, in the low-temperature environment, the compactness of the oxide layer manufactured using the related art is low, which may lead to a decrease in the reliability of the semiconductor device including the oxide layer. For example, the oxide layer with lower compactness has a large number of defects that may capture/un-capture channel carriers and affect device electrostatics and carrier transport in the channel, thereby leading to bias temperature instability (BTI) problems. In order to solve this problem, in the related art, high-temperature annealing and other high-temperature processing methods are usually used. Although this method solves the problem of poor compactness of the oxide layer, high temperature may cause thermal damage to the semiconductor structure, and the adjustment range and the adjustment accuracy of the thickness of the oxide layer are poor, so that the performance and reliability of the semiconductor device including the oxide layer are still poor. In contrast, the embodiments of the present disclosure provide a method for manufacturing an oxide layer, which combines pre-oxidation and oxygen plasma treatment in a low-temperature environment. In this way, the compactness of the pre-formed first oxide layer is improved, and the thickness of the second oxide layer may be precisely controlled by adjusting treatment parameters of the oxygen plasma treatment. This not only obtains a second oxide layer with higher compactness, but also overcomes the technical bias of poor compactness of the oxide layer manufactured by low-temperature methods in the related art, ensuring the reliability of the semiconductor device including the second oxide layer.

In the actual manufacturing process, the specific structure of the semiconductor structure is not specifically limited by the embodiments of the present disclosure, and may be determined according to actual requirements. Specifically, the semiconductor structure may be a semiconductor substrate on which no structure is formed. Alternatively, the semiconductor structure may also be a structure formed with some corresponding functions and made of at least semiconductor materials. The specific structure of the semiconductor structure may be determined according to the actual application scene, as long as an oxide layer may be formed on the semiconductor structure.

For example, referring to FIG. 2, the semiconductor substrate 100 on which no structure is formed may be a bare wafer.

For example, the semiconductor structure may include a source region, a drain region, and a channel region located between the source region and the drain region. The channel region is in contact with the source region and the drain region at two sides of the channel region in a length direction of the channel region. The second oxide layer is formed on the periphery of the channel region.

In a case of adopting the above technical solution, since the second oxide layer manufactured by the method for manufacturing the oxide layer provided by the embodiments of the present disclosure has a relatively thin thickness, the method for manufacturing the oxide layer provided by the embodiments of the present disclosure may be used as the method for

### Manufacturing the Interface Layer.

Regarding the material of the semiconductor structure mentioned above, the embodiments of the present disclosure do not limit the material of the semiconductor structure. The material of the semiconductor structure may be determined according to the specific types of structures included in the semiconductor structure and actual requirements, as long as it may be applied to the method for manufacturing the oxide layer provided by the embodiments of the present disclosure. For example, the material of the semiconductor structure may include silicon, germanium, germanium silicon, or any other possible semiconductor material.

Optionally, the material of the semiconductor structure includes silicon.

In a case of adopting the above technical solution, the method for manufacturing the oxide layer provided by the embodiments of the present disclosure has good compatibility with the most common related material (that is, silicon), thereby expanding the application scope of the method for manufacturing the oxide layer provided by the embodiments of the present disclosure.

As for the compactness of the first oxide layer, the compactness of the first oxide layer as a pre-oxide layer for the second oxide layer needs to be lower than the compactness of the second oxide layer, so that when the second oxide layer is formed by oxygen plasma treatment, oxygen plasma may enter the looser first oxide layer and process the first oxide layer and a part of the semiconductor structure, so as to form the second oxide layer.

As for the thickness of the first oxide layer, the embodiments of the present disclosure do not limit the thickness of the first oxide layer. The thickness of the first oxide layer may be determined according to the material of the semiconductor structure, the thickness of the second oxide layer, and actual requirements, as long as it may be applied to the method for manufacturing the oxide layer provided by the embodiments of the present disclosure.

For example, the first oxide layer serves as a pre-oxide layer for the second oxide layer, and the first oxide layer may have a thinner thickness to meet various requirements for the subsequent formation of the second oxide layer, such as the thickness of the second oxide layer, the thermal budget of forming the second oxide layer, etc.

In the actual manufacturing process, the thickness of the second oxide layer formed from the first oxide layer is not specifically limited in the embodiments of the present disclosure, and may be determined according to actual requirements.

Specifically, since the second oxide layer is partially formed by a semiconductor structure, the thickness of the second oxide layer may be determined according to the material of the semiconductor structure and the specific types of structures included in the semiconductor structure. Alternatively, the thickness of the second oxide layer may also be determined according to the thermal budget set for the manufacturing method provided by the embodiments of the present disclosure and actual requirements. Alternatively, since the first oxide layer serves as a pre-oxide layer for the second oxide layer, the thickness of the second oxide layer may be greater than or equal to the thickness of the first oxide layer.

For example, the thickness of the second oxide layer manufactured by the method for manufacturing the oxide layer provided by the embodiments of the present disclosure is greater than or equal to 0.5 nm and less than or equal to 5 nm. Specifically, the thickness of the second oxide layer may be 0.5 nm, 1 nm, 2 nm, 3 nm, 4 nm, or 5 nm, etc.

In a case of adopting the above technical solution, the thickness of the second oxide layer may be adjusted within a large range, and the second oxide layer may have a larger application range, thereby expanding the application scope of the method for manufacturing the oxide layer provided by the embodiments of the present disclosure.

The function of the second oxide layer may be determined according to the parameters of the second oxide layer manufactured by the method for manufacturing the oxide layer provided by the embodiments of the present disclosure. For example, the second oxide layer may be a passivation layer, a doping barrier layer, or an interface oxide layer.

Optionally, the second oxide layer may be an interface oxide layer. The second oxide layer manufactured by the method for manufacturing the oxide layer provided by the embodiments of the present disclosure has a thinner thickness, and the method for manufacturing the oxide layer provided by the embodiments of the present disclosure may be used as the method for manufacturing the interface oxide layer.

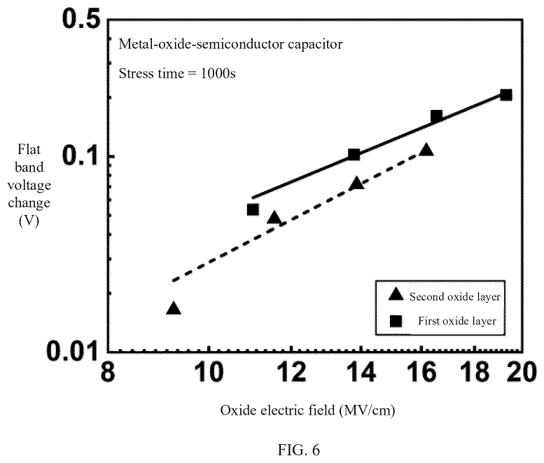

Regarding the compactness and quality improvement of the second oxide layer after oxygen plasma treatment compared to the first oxide layer, referring to FIG. 6, the first oxide layer and the second oxide layer are used as dielectric layers for a metal-oxide-semiconductor capacitor. Under a temperature of 125° C., comparing a flat band voltage degradation of a capacitor of the first oxide layer as the dielectric layer for the metal-oxide-semiconductor capacitor with a flat band voltage degradation of a capacitor of the second oxide layer as the dielectric layer for the metal-oxide-semiconductor capacitor after 1000 seconds of constant electric field stress, the flat band voltage degradation of the capacitor of the second oxide layer as the dielectric layer for the metal-oxide-semiconductor capacitor is smaller, which indicates that the second oxide layer has fewer primary defects and generates fewer defects during stress processing, that is the second oxide layer has better compactness, quality and reliability. The second oxide layer manufactured in the embodiments of the present disclosure meets at least the compactness requirements mentioned above.

In the actual manufacturing process, the specific temperature of the first low-temperature environment mentioned above may be determined according to the specific structure and materials of the semiconductor structure, as well as actual requirements, which will not be specifically limited here. Specifically, for the first low-temperature environment mentioned above, the following conditions requires to be met: firstly, the thermal budget of forming the first oxide layer in the first low-temperature environment and the thermal budget of forming the second oxide layer in the second low-temperature environment requires to not exceed the requirements for thermal budget when specifically implementing the method for manufacturing the oxide layer provided by the embodiments of the present disclosure; secondly, the first oxide layer can be formed within this temperature range, and the first oxide layer requires to meet the compactness requirements for subsequent oxygen plasma treatment.

For example, the temperature of the first low-temperature environment may be less than or equal to 400° C. For example, the temperature of the first low-temperature environment may be 50° C., 80° C., 100° C., 120° C., 150° C., 180° C., 200° C., 220° C., 260° C., 280° C., 300° C., 320° C., 340° C., 360° C., 380° C., or 400° C., etc.

The embodiments of the present disclosure do not specifically limit the method for forming the first oxide layer on the semiconductor structure, as long as it may form the first oxide layer that meets the compactness and thickness requirements for subsequent oxygen plasma treatment in the first low-temperature environment. For example, the method for forming the first oxide layer on the semiconductor structure includes liquid phase deposition (LPD), low-temperature chemical vapor deposition, or aqueous ozone solution method.

Optionally, the method for forming the first oxide layer on the semiconductor structure is the aqueous ozone solution method. Specifically, the formation of the first oxide layer on the semiconductor structure through the aqueous ozone solution method involves submerging the semiconductor structure in an aqueous ozone solution to oxidize the semiconductor structure, so as to form the first oxide layer.

In a case of adopting the above technical solution, a relatively loose and non-compact first oxide layer may be formed by pre-oxidizing the semiconductor structure using ozone water oxidation, which facilitates the oxygen plasma to enter the first oxide layer and to oxidize the first oxide layer and the part of the semiconductor structure when the subsequent oxygen plasma treatment is performed on the semiconductor structure, so as to form the second oxide layer. Moreover, the semiconductor structure is pre-oxidized using the ozone water oxidation, and the thickness of the formed first oxide layer is relatively thin, which may avoid the thickness of the subsequent formed second oxide layer does not meet a practical requirement (e.g. when the second oxide layer is a thinner oxide layer such as an interface layer) due to the large thickness of the first oxide layer, thereby reducing the thickness range of the oxide layer manufactured by the method for manufacturing the oxide layer provided by the embodiments of the present disclosure. In addition, since a solution wet processing is used, the temperature of the first low-temperature environment is lower, which is beneficial for reducing the thermal budget of the method for manufacturing the oxide layer provided by the embodiments of the present disclosure.

In addition, when the semiconductor structure includes the source region, drain region and channel region mentioned above, the second oxide layer serves as the interface layer. The first oxide layer formed by pre-oxidation of the semiconductor structure using ozone water oxidation has a thinner thickness, which is beneficial for achieving a thinner thickness of the second oxide layer, thereby achieving the manufacturing of a thinner interface layer under low-temperature condition.

As a possible embodiment, the ozone concentration in the above-mentioned aqueous ozone solution is greater than or equal to 3 ppm and less than or equal to 100 ppm. For example, the ozone concentration in the above-mentioned aqueous ozone solution may be 3 ppm, 10 ppm, 20 ppm, 30 ppm, 40 ppm, 50 ppm, 60 ppm, 70 ppm, 80 ppm, 90 ppm, or 100 ppm, etc.

In a case of adopting the above technical solution, the ozone concentration in the aqueous ozone solution is within the above range, which may avoid that the formed oxide layer with poor compactness, poor quality and too thin thickness since the ozone concentration is too low, and may further avoid higher energy required for subsequent oxygen plasma treatment (which requires greater radio frequency power, longer treatment time and higher treatment temperature), thereby ensuring the thermal budget of the method for manufacturing the oxide layer provided by the embodiments of the present disclosure. Moreover, a large amount of ozone escaping from the solution due to the too high ozone concentration may also be avoided, which is beneficial for reducing the usage amount of consumables and controlling manufacturing costs.

As a possible embodiment, the oxidation time of submerging the semiconductor structure in the aqueous ozone solution is greater than or equal to 3 seconds and less than or equal to 100 seconds. For example, the oxidation time of submerging the semiconductor structure in the aqueous ozone solution may be 3 seconds, 10 seconds, 20 seconds, 30 seconds, 40 seconds, 50 seconds, 60 seconds, 70 seconds, 80 seconds, 90 seconds, or 100 seconds, etc.

In a case of adopting the above technical solution, the oxidation time of submerging the semiconductor structure in the aqueous ozone solution is within the above range, which may avoid that the formed first oxide layer with poor compactness and poor quality since the oxidation time is too short, and may further avoid higher energy required for subsequent oxygen plasma treatment (which requires greater radio frequency power, longer treatment time and higher treatment temperature), thereby ensuring the thermal budget of the method for manufacturing the oxide layer provided by the embodiments of the present disclosure. Moreover, the excessive amount of ozone escaping from the solution due to the too long oxidation time may also be avoided, which is beneficial for reducing the usage amount of consumables and controlling manufacturing costs.

As for the temperature range of the second low-temperature environment, its specific temperature may be determined according to the specific structure and materials of the semiconductor structure, the compactness and thickness requirements for the second oxide layer, and actual requirements, which will not be specifically limited here. Specifically, the temperature range of the second low-temperature environment requires to meet the following conditions: firstly, the thermal budget of forming the first oxide layer in the first low-temperature environment and the thermal budget of forming the second oxide layer in the second low-temperature environment requires to not exceed the requirements for thermal budget when specifically implementing the method for manufacturing the oxide layer provided by the embodiments of the present disclosure; secondly, within this temperature range, the second oxide layer formed by oxygen plasma treatment requires to meet the compactness and thickness requirements mentioned above.

For example, the temperature of the second low-temperature environment is less than or equal to 400° C. For example, the temperature of the second low-temperature environment may be 50° C., 80° C., 100° C., 120° C., 150° C., 180° C., 200° C., 220° C., 260° C., 280° C., 300° C., 320° C., 340° C., 360° C., 380° C., or 400° C., etc.

In a case of adopting the above technical solution, the treatment temperature of the oxygen plasma treatment is within the above range, which may avoid the thickness and compactness of the formed second oxide layer do not meet the above requirements due to too low treatment temperature. In addition, the treatment temperature of the oxygen plasma treatment is within the above range, which may also avoid a significant increase in thermal budget due to excessively high treatment temperature, thereby ensuring the thermal budget of the method for manufacturing the oxide layer provided by the embodiments of the present disclosure.

As for the radio frequency power of the oxygen plasma treatment, in the method for manufacturing the oxide layer provided by the embodiments of the present disclosure, the radio frequency power of the oxygen plasma treatment is greater than or equal to 500 W and less than or equal to 1000 W. For example, the radio frequency power of the oxygen plasma treatment may be 500 W, 600 W, 700 W, 800 W, 900 W, or 1000 W, etc.

In a case of adopting the above technical solution, the radio frequency power of the oxygen plasma treatment is within the above range, which may avoid the problem that after forming the second oxide layer with a certain thickness, the energy of the oxygen plasma is too low to effectively penetrate the first oxide layer and semiconductor structure since the radio frequency power is too low, and may further avoid the second oxide layer formed by oxygen plasma treatment reach a saturation thickness which cannot be further increased, thereby ensuring the adjustment range of the thickness of the oxide layer formed by the method for manufacturing the oxide layer provided by the embodiments of the present disclosure. An incomplete ionization of oxygen due to the too low radio frequency power may also be avoided, which may further avoid poor oxidation of oxygen plasma, thereby ensuring the compactness and quality of the second oxide layer formed by oxygen plasma treatment to meet the above requirements. Excessive reflection generated by oxygen plasma bombardment of the first oxide layer and semiconductor structure due to the too large radio frequency power of the oxygen plasma treatment may also be avoided, which may further avoid damage to the oxygen plasma treatment device, thereby ensuring the normal operation of the device.

As for the treatment time of the oxygen plasma treatment, in the method for manufacturing the oxide layer provided by the embodiments of the present disclosure, the treatment time of the oxygen plasma treatment is greater than or equal to 5 seconds and less than or equal to 1 hour.

In a case of adopting the above technical solution, the treatment time of the oxygen plasma treatment is within the above range, which may avoid the compactness and thickness of the formed second oxide layer do not meet the above requirements due to too short treatment time, thereby ensuring the performance of the oxide layer manufactured by the method for manufacturing the oxide layer provided by the embodiments of the present disclosure. Moreover, a significant increase in thermal budget due to too long treatment time of the oxygen plasma treatment may also be avoided, thereby ensuring the thermal budget of the method for manufacturing the oxide layer provided by the embodiments of the present disclosure.

In addition, the relationship between the increased thickness of the second oxide layer compared to the first oxide layer and the treatment time of the oxygen plasma treatment may be accurately described, so that the thickness of the second oxide layer may be precisely controlled by controlling the time of the oxygen plasma treatment. For example, referring to FIG. 5, in a case that the radio frequency power is 900 W and the treatment temperature of the oxygen plasma treatment is 250° C., the relationship between the increased thickness of the second oxide layer compared to the first oxide layer and the time of the oxygen plasma treatment may be accurately described. From FIG. 5, it may be seen that the thickness of the oxide layer manufactured by the method for manufacturing the oxide layer provided by the embodiments of the present disclosure may be adjusted in a large range and the adjustment accuracy is high.

In the second aspect, the embodiments of the present disclosure provide a semiconductor device, including a semiconductor structure and a second oxide layer disposed on the semiconductor structure. The second oxide layer is manufactured and formed using the manufacturing method provided in the first aspect. The beneficial effects of the semiconductor device provided by the embodiments of the present disclosure may refer to the related description of the first aspect, which will not be repeated here.

In the description of the above embodiments, specific features, structures, materials, or characteristics may be combined in any one or more embodiments or examples in a suitable manner.

The descriptions above are only specific embodiments of the present disclosure, but the scope of protection of the present disclosure is not limited to this. Any those skilled in the art familiar with the technical field may easily think of changes or substitutions within the technical scope disclosed in the present disclosure, which should be included in the scope of protection of the present disclosure. Therefore, the scope of protection of the embodiments of the present disclosure should be based on the scope of protection of the claims.

What is claimed is:

1. A method for manufacturing an oxide layer, comprising:
providing a semiconductor structure;
forming a first oxide layer on the semiconductor structure in a first low-temperature environment; and
applying an oxygen plasma treatment on the first oxide layer and a part of the semiconductor structure in a second low-temperature environment to obtain a second oxide layer, wherein a compactness of the second oxide layer is greater than a compactness of the first oxide layer.

2. The method according to claim 1, wherein a temperature of the first low-temperature environment and/or the second low-temperature environment is less than or equal to 400° C.

3. The method according to claim 1, wherein the forming a first oxide layer on the semiconductor structure comprises:
submerging the semiconductor structure in an aqueous ozone solution to oxidize the semiconductor structure, so as to form the first oxide layer.

4. The method according to claim 3, wherein an ozone concentration in the aqueous ozone solution is greater than or equal to 3 ppm and less than or equal to 100 ppm; and/or,
wherein an oxidation time of submerging the semiconductor structure in the aqueous ozone solution is greater than or equal to 3 seconds and less than or equal to 100 seconds.

5. The method according to claim 1, wherein a thickness of the second oxide layer is greater than or equal to 0.5 nm and less than or equal to 5 nm.

6. The method according to claim 1, wherein a treatment temperature during the oxygen plasma treatment is greater than or equal to 200° C. and less than or equal to 300° C.

7. The method according to claim 1, wherein a radio frequency power of the oxygen plasma treatment is greater than or equal to 500 W and less than or equal to 1000 W.

8. The method according to claim 1, wherein a treatment time of the oxygen plasma treatment is greater than or equal to 5 seconds and less than or equal to 1 hour.

9. The method according to claim 1, wherein the second oxide layer comprises an interface oxide layer; and/or,
wherein a material of the semiconductor structure comprises silicon; and/or,
wherein the semiconductor structure comprises a source region, a drain region, and a channel region located between the source region and the drain region; the channel region is in contact with the source region and the drain region at two sides of the channel region in a length direction of the channel region; and the second oxide layer is formed on a periphery of the channel region.

10. A semiconductor device, comprising: a semiconductor structure and a second oxide layer disposed on the semiconductor structure, wherein the second oxide layer is manufactured and formed using the method of claim 1.
